(19) United States
(12) Patent Application Publication
(10) Pub. No.: US 2025/0183238 A1
(43) Pub. Date: Jun. 5, 2025

(54) STACK CHIP PACKAGE

(71) Applicant: SK hynix Inc., Gyeonggi-do (KR)

(72) Inventor: Dong Sop LEE, Gyeonggi-do (KR)

(21) Appl. No.: 18/645,374

(22) Filed: Apr. 25, 2024

(30) Foreign Application Priority Data
Nov. 30, 2023 (KR) 10-2023-0171279

(51) Int. Cl. H01L 25/16; H01L 23/00; H01L 23/31; H01L 25/065; H10B 80/00

(52) U.S. Cl. CPC H01L 25/16; H01L 23/315; H01L 24/32; H01L 24/33; H01L 24/48; H01L 24/73; H10B 80/00; H01L 25/0657; H01L 2224/32145; H01L 2224/32225; H01L 2224/33181; H01L 2224/48091; H01L 2224/48145; H01L 2224/48227; H01L 2224/73215; H01L 2224/73265; H01L 2225/06506; H01L 2225/0651; H01L 2225/06562; H01L 2924/1431; H01L 2924/1432; H01L 2924/1433; H01L 2924/1436; H01L 2924/1437; H01L 2924/1438; H01L 2924/1441; H01L 2924/1443; H01L 2924/14511

(57) ABSTRACT

A stack chip package includes a first stack structure, a second stack structure and a passive element. The first and second stack structures include a plurality of semiconductor chips stacked on a package substrate, respectively. The first stack structure has a first sidewall portion and a second sidewall portion. The plurality of the semiconductor chips in the first stack structure are stacked on the first sidewall portion to form a first concave portion and a first protrusion alternately arranged. The second stack structure has a third sidewall portion and a fourth sidewall portion. The third sidewall portion faces the first sidewall portion. The plurality of the semiconductor chips in the second stack structure are stacked on the third sidewall portion to form a second concave portion and a second protrusion alternately arranged. The first concave portion faces the second protrusion. The first protrusion faces the second concave portion.

### CROSS-REFERENCES TO RELATED APPLICATION

The present application claims priority under 35 U.S.C. § 119(a) to Korean application number 10-2023-0171279, filed on Nov. 30, 2023, which is incorporated herein by reference in its entirety.

### BACKGROUND

### 1. Technical Field

Various embodiments of the present disclosure generally relate to a stack chip package and, more particularly, to a stack chip package capable of securing an integration area of a passive element.

### 2. Related Art

Recently, for addressing the need of electronic devices for faster operations, and for processing massive amount of data, a great number of semiconductor chips are being built in a single semiconductor package.

Typically, the semiconductor chips may be stacked on a package substrate. Further, to provide the semiconductor package with various performances, at least one passive element may be mounted on the semiconductor package. Thus, it may be required to effectively arrange the semiconductor chips and the passive element in a restricted area of the semiconductor package.

### SUMMARY

Various embodiments of the present disclosure provide a stack chip package capable of securing an area where a passive element may be integrated in a restricted area.

According to an embodiment, there is provided a stack chip package which includes a package substrate, a first stack structure, a second stack structure and a passive element. The first stack structure may include a plurality of semiconductor chips stacked on the package substrate. The first stack structure may have a first sidewall portion and a second sidewall portion. The plurality of the semiconductor chips in the first stack structure may be stacked on the first sidewall portion to form a first concave portion and a first protrusion alternately arranged. The second stack structure may include a plurality of semiconductor chips stacked on the package substrate. The second stack structure may have a third sidewall portion and a fourth sidewall portion. The third sidewall portion may face the first sidewall portion. The plurality of the semiconductor chips in the second stack structure may be stacked on the third sidewall portion to form a second concave portion and a second protrusion alternately arranged. The passive element may be integrated on at least one portion of the package substrate outside the second sidewall portion of the first stack structure and the fourth sidewall portion of the second stack structure. The first concave portion may face the second protrusion. The first protrusion may face the second concave portion.

In some embodiments, a thickness of the first concave portion may correspond to a thickness of the second protrusion. A thickness of the first protrusion may correspond to a thickness of the second concave portion.

In some embodiments, the stack chip package may further include an insulating adhesive layer configured to attach the semiconductor chips of the first and second stack structures to each other.

In some embodiments, a thickness of the first concave portion and the first protrusion may be a sum of a thickness of the semiconductor chips and a thickness of the insulating adhesive layer in the first stack structure. A thickness of the second concave portion and the second protrusion may be a sum of a thickness of the semiconductor chips and a thickness of the insulating adhesive layer in the second stack structure.

In some embodiments, the stack chip package may further include a gap-forming layer interposed between at least one of the semiconductor chips in the first stack structure, or between at least one of the semiconductor chips in the second stack structure to secure the thicknesses of the first and second concave portions and the thicknesses of the first and second protrusions.

According to various embodiments, there may be provided a stack chip package. The stack chip package may include a package substrate, a first stack structure, a second stack structure and a passive element. The first stack structure may include a plurality of semiconductor chips stacked on the package substrate. The semiconductor chips of the first stack structure may be arranged in a zigzag pattern to expose pads on an edge portion of each of the semiconductor chips. The first stack structure may have a first sidewall portion and a second sidewall portion. The plurality of the semiconductor chips in the first stack structure may be stacked on the first sidewall portion to form a first concave portion and a first protrusion alternately arranged. The second stack structure may be arranged at one side of the first sidewall portion of the first stack structure. The second stack structure may include a plurality of semiconductor chips stacked on the package substrate. The semiconductor chips of the second stack structure may be arranged in a zigzag pattern to expose an edge portion of each of the semiconductor chips. The second stack structure may have a third sidewall portion and a fourth sidewall portion. The third sidewall portion may face the first sidewall portion. The plurality of the semiconductor chips in the second stack structure may be stacked on the third sidewall portion to form a second concave portion and a second protrusion alternately arranged. The passive element may be integrated on at least one portion of the package substrate outside the second sidewall portion of the first stack structure and the fourth sidewall portion of the second stack structure. The first concave portion may face the second protrusion. The first protrusion may face the second concave portion.

In some embodiments, a distance between the first concave portion and the second protrusion may be substantially the same as a distance between the first protrusion and the second concave portion.

In some embodiments, a distance between the first concave portion and the second protrusion, a distance between the first protrusion and the second concave portion and a distance between the first protrusion and the second protrusion may be substantially equal to each other.

According to various embodiments, there may be provided a stack chip package. The stack chip package may include first and second stack structures. The first and second stack structures may be positioned adjacent to each other. Each of the first and second stack structures has uneven sidewalls including alternating protruding and concave portions. A concave portion of one of the first stack structures is positioned adjacent to a concave portion of the second stack structure and vice versa thus reducing the overall footprint area of the stack chip package.

According to various embodiments of the present disclosure, a stack shape of the semiconductor chips in the stack structure may be changed to secure a space where the passive element may be mounted. Signals and power quality of the semiconductor chips may be improved by mounting the passive element.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a cross-sectional view illustrating a stack chip package in accordance with an embodiment of the present disclosure;

FIG. 2 is a perspective view illustrating a stack chip package in accordance with an embodiment of the present disclosure;

FIGS. 3 to 12 are cross-sectional views illustrating a stack chip package in accordance with embodiments of the present disclosure;

FIG. 13 is a cross-sectional view illustrating a stack chip package with a gap-forming layer in accordance with an embodiment of the present disclosure;

FIG. 14 is a perspective view illustrating a stack chip package with a gap-forming layer in accordance with an embodiment of the present disclosure; and

FIG. 15 is a cross-sectional view illustrating a stack chip package in accordance with an embodiment of the present disclosure.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of embodiments of the present disclosure. However, embodiments of the present disclosure should not be construed as limiting the inventive concept. Although a few embodiments of the present disclosure will be shown and described, it will be appreciated by those of ordinary skill in the art that changes may be made in these embodiments without departing from the principles and spirit of the present disclosure.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, spatially relative terms, such as “beneath,” “below,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout.

In various embodiments, a semiconductor device may include a semiconductor chip, a semiconductor package including a plurality of semiconductor chips, etc.

The semiconductor chip may include a semiconductor wafer, a semiconductor dies in which an electronic part and circuits may be integrated. The semiconductor chip may include a memory chip with a memory integrated circuit such as a DRAM, an SRAM, a NAND flash, a NOR flash, an MRAM, a ReRAm, an FeRAM, a PcRAM, etc., a processor having a logic with a logic circuit, an ASIC chip, an application processor (AP), a graphic processing unit (GPU), a central processing unit (CPU), a system on chip (SOC), etc.

The semiconductor device may be applied to an information communication device, an electronic device related to a bio technology, a health care technology, etc., a wearable electronic device, etc. Particularly, the semiconductor device may be applied to an internet of things (IoT).

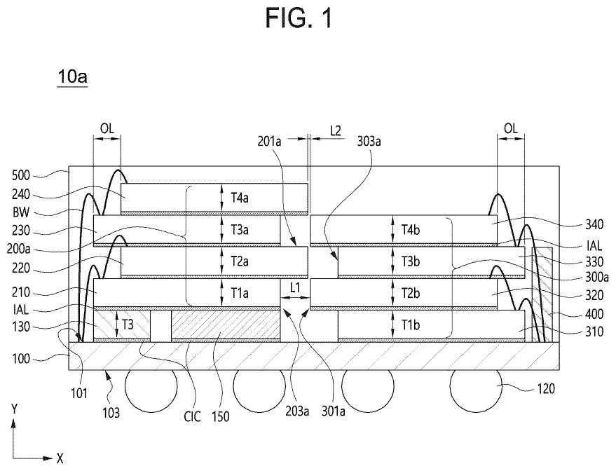

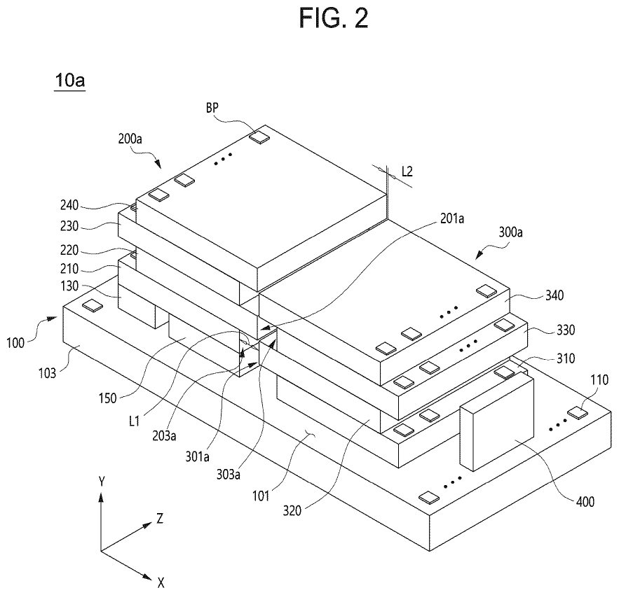

FIG. 1 is a cross-sectional view illustrating a stack chip package in accordance with an embodiment of the present disclosure and FIG. 2 is a perspective view illustrating a stack chip package in accordance with an embodiment of the present disclosure.

Referring to FIGS. 1 and 2, a stack chip package 10a of some embodiments may include a package substrate 100, a first stack structure 200a and a second stack structure 300a.

The package substrate 100 may include at least one of a printed circuit board (PCB), an interposer and a flexible PCB.

The package substrate 100 may include a plurality of interconnect structures configured to transmit signals in the package substrate 100.

The package substrate 100 may include a first surface 101 and a second surface 103. A plurality of conductive pads may be formed on an edge portion of the first surface 101 of the package substrate 100. The conductive pads may be connected with the interconnect structures. The first stack structure 200a and the second stack structure 300a may be arranged on the first surface 101 of the package substrate 100 in a horizontal direction X.

External terminals 120, for example, solder balls may be attached to the second surface 103 of the package substrate 100. The external terminals 120 may receive signals and voltage for driving the stack chip package 10a from an external device.

The first stack structure 200a and the second stack structure 300a may be spaced apart from each other on the first surface 101 of the package substrate 100.

For example, the first stack structure 200a may include first to fourth semiconductor chips 210, 220, 230 and 240 sequentially stacked in a vertical direction Y. The second stack structure 300a may include fifth to eighth semiconductor chips 310, 320, 330 and 340 sequentially stacked in the vertical direction Y.

The stack chip package 10a may further include at least one support 130 and a control chip 150.

The support 130 may be arranged between one of the first stack structure 200a and the second stack structure 300a and the first surface 101 of the package substrate 100. In an embodiment, the support 130 may be interposed between the first stack structure 200a and the package substrate 100. The support 130 may lift the first stack structure 200a from the first surface 101 of the package substrate 100 by a thickness of the support 130 to support the first stack structure 200a. The support 130 may function to maintain a gap between the first stack structure 200a and the second stack structure 300a. The support 130 may stably support the first stack structure 200a to secure a space where the control chip 150 may be formed.

For example, the support 130 may have a size smaller than a size of the first semiconductor chip 210 of the first stack structure 200a. The support 130 may be positioned on one side of an edge portion on a lower surface of the first stack structure 200a to provide the space where the control chip 150 may be formed between the package substrate 100 and the first stack structure 200a.

In some embodiments, the support 130 may include a dummy chip, a dielectric block, etc. The support 130 may have a thickness T3 determined in accordance with a thickness of the control chip 150.

The control chip 150 may include a logic circuitry configured to control the first to fourth semiconductor chips 210, 220, 230 and 240 of the first stack structure 200a and the fifth and eighth semiconductor chips 310, 320, 330 and 340 of the second stack structure 300a. The control chip 150 may be arranged in the space provided by the support 130. Thus, the control chip 150 may be positioned between the first stack structure 200a and the package substrate 100. The control chip 150 may be spaced apart from the support 130 by a gap.

In some embodiments, the control chip 150 and/or the support 130 may be electrically attached to the package substrate 100 by a conductive inner connector (CIC). A lowermost semiconductor chip of the second stack structure 300a, i.e., the fifth semiconductor chip 310 may be electrically connected to the package substrate 100 by the CIC. The CIC may include a bump and a conductive member.

The support 130 and the control chip 150 may be attached to the first stack structure 200a by an insulating adhesive layer IAL.

Hereinafter, the first stack structure 200a and the second stack structure 300a are illustrated in detail. In some embodiments, a position relatively closer to the package substrate 100 may be referred to as a lower portion or a lower end. A position relatively remote from the package substrate 100 may be referred to as an upper portion or an upper end. When the stack chip package may be reversed, a position closer to the package substrate 100 may be referred to as the upper portion or the upper end. A position remote from the package substrate 100 may be referred to as the lower portion or the lower end.

The first stack structure 200a may include a first sidewall portion and a second sidewall portion. The first sidewall portion may be adjacent to the second stack structure 300a. For example, when the second stack structure 300a is located at a right side of the first stack structure 200a, the first sidewall portion may be a left sidewall of the first stack structure 200a and the second sidewall portion may be a right sidewall of the first stack structure 200a. The second sidewall portion may be remote from the second structure 300a. The second stack structure 300a may include a third sidewall portion and a fourth sidewall portion. The third sidewall portion may be adjacent to the first sidewall portion of the first stack structure 200a. The third sidewall portion may face the first sidewall portion. The fourth sidewall portion may be spaced apart from the first stack structure 200a.

The first to fourth semiconductor chips 210, 220, 230 and 240 may be stacked on the first sidewall portion of the first stack structure 200a to form a first uneven structure. The first uneven structure may include at least one first protrusion 201a and at least one first concave portion 203a.

For example, the first sidewall portions of the even numbered semiconductor chips 220 and 240 among the first to fourth semiconductor chips 210, 220, 230 and 240 may be protruded from the first sidewall portions of the odd numbered semiconductor chips 210 and 230 to form the first protrusion 201 on the first sidewall portions of the second and fourth semiconductor chips 220 and 240 and the first concave portion 203a on the first sidewall portion of the first and third semiconductor chips 210 and 230.

When the first to fourth semiconductor chips 210, 220, 230 and 240 have substantially the same size, the first concave portion 203a may be formed on the second sidewall portions of the second and fourth semiconductor chips 220 and 240 and the first protrusion 201a may be defined on the second sidewall portions of the first and third semiconductor chips 210 and 230.

The zigzag pattern of the first to fourth semiconductor chips 210, 220, 230 and 240 in the first stack structure 200a may be configured to expose pads on the upper and the lower surfaces of the first to fourth semiconductor chips 210, 220, 230 and 240, thereby improving efficiency.

The fifth to eighth semiconductor chips 310, 320, 330 and 340 may also be stacked in a zigzag pattern to form at least one second protrusion 301a and at least one second concave portion 303a at the third sidewall portion of the second stack structure 300a. The stacking of the fifth to eighth semiconductor chips 310, 320, 330 and 340 may be substantially the same as the stacking of the first to fourth semiconductor chips 210, 220, 230 and 240.

For example, the third sidewall portions of the sixth and eighth semiconductor chips 320 and 340 may be protruded from the third sidewall portions of the fifth and seventh semiconductor chips 310 and 330 toward the first sidewall portion to form the second protrusion 301a at the third sidewall portions of the sixth and eighth semiconductor chips 320 and 340 and the second concave portion 303a at the third sidewall portions of the fifth and seventh semiconductor chips 310 and 330.

When the fifth to eighth semiconductor chips 310, 320, 330 and 340 have substantially the same size, the second concave portion 303a may be formed at the fourth sidewall portions of the sixth and eighth semiconductor chips 320 and 340 and the second protrusions 301a at the fourth sidewall portions of the fifth and seventh semiconductor chips 310 and 330.

In some embodiments, the first and second stack structures 200a and 300a may be arranged such that the first concave portions 203a at the first sidewall of the first stack structure 200a may face the second protrusions 301a at the third sidewall portion of the second stack structure 300a by a gap L1. The first protrusions 201a at the first sidewall of the first stack structure 200a may face the second concave portions 303a at the third sidewall portion of the second stack structure 300a by the gap L1.

In some embodiments, the support 130 and the control chip 150 may provide the first stack structure 200a with a height such that the first concave portions 203a at the first sidewall of the first stack structure 200a may face the second protrusions 301a at the third sidewall portion of the second stack structure 300a by the gap L1. The first protrusions 201a at the first sidewall of the first stack structure 200a may face the second concave portions 303a at the third sidewall portion of the second stack structure 300a by the gap L1.

Therefore, integration areas of the first and second stack structures 200a and 300a on the package substrate 100 may be reduced. Further, an integration area of the control chip may not be necessary to secure an integration area of the passive element.

Particularly, in a general stack structure, semiconductor chips may be stacked in a zigzag pattern to expose edge pads of the semiconductor chips for wiring bonds. Because the stack structures may be symmetrical with each other on a package substrate, protrusions and concave portions at sidewalls of the stack structures may face each other, respectively. Thus, the stack structures may have a width between the facing protrusions. As a result, the stack structure may have a width wider than a width of the semiconductor chip so that the stack structure on the package substrate may have a large occupying area to reduce an integration area of the passive element.

In contrast, according to the first and second stack structures 200a and 330a of some embodiments, the first concave portions 203a at the first sidewall of the first stack structure 200a may face the second protrusions 301a at the third sidewall portion of the second stack structure 300a by a gap L1. The first protrusions 201a at the first sidewall of the first stack structure 200a may face the second concave portions 303a at the third sidewall portion of the second stack structure 300a by the gap L1. Thus, the length of the first protrusion 201a and the first concave portion 203a in the first stack structure 200a may be offset to the length of the second protrusion 301a and the second concave portion 303a in the second stack structure 300a to reduce the width of the first and second stack structures 200a and 300a. Reference numeral OL refers to the length of the protrusions which may be from about 0.1 mm to about 0.5 mm. The gap L1 may isolate the first and second stack structures 200a and 300a. Thus, allow them to have different electrical characteristics.

The first to fourth semiconductor chips 210, 220, 230 and 240 may be attached to the fifth to eighth semiconductor chips 310, 320, 330 and 340, respectively, using an insulating adhesive layer IAL. For example, the insulating adhesive layer IAL may be formed on bottom surfaces of the first to eighth semiconductor chips 210, 220, 230, 240, 310, 320, 330 and 340.

The insulating adhesive layer IAL may include a die attach film (DAF). The insulating adhesive layer IAL may have various thicknesses. Although the insulating adhesive layer IAL is shown to have a thinner thickness than each of the semiconductor chips 210, 220, 230, 240, 310, 320, 330 and 340 in the FIG. 4, the insulating adhesive layer IAL may also have substantially equal to or thicker thickness than each of the semiconductor chips 210, 220, 230, 240, 310, 320, 330 and 340.

Particularly, the insulating adhesive layer IAL may be positioned between the first protrusion 201a of the first sidewall portion and the second protrusion 301a of the third sidewall portion adjacent to the first protrusion 201a to prevent an electrical short between the first stack structure 200a and the second stack structure 300a.

More particularly, a gap L2 between the first and second protrusions 201a and 301a at the first and third sidewall portions may be narrower than the gap L1. However, the insulating adhesive layer IAL between the first and second protrusions 201a and 301a may prevent an electrical short between the semiconductor chips with the first and second protrusions 201a and 301a.

For example, a thickness T3 of the support 130 may be substantially the same as a thickness T1b of the fifth semiconductor chip 310. Alternatively, a thickness of a conductive adhesive layer CIC on a bottom surface of the support 130 may be substantially the same as a thickness of a conductive adhesive layer CIC on a bottom surface of the fifth semiconductor chip 310.

Further, the first to eighth semiconductor chips 210, 220, 230, 240, 310, 320, 330 and 340 may be substantially of the same type. For example, the first to eighth semiconductor chips 210, 220, 230, 240, 310, 320, 330 and 340 may be a memory chip such as a NAND flash memory, but the embodiments are not limited thereto. The first to eighth semiconductor chips 210, 220, 230, 240, 310, 320, 330 and 340 may be a non-volatile memory chip such as a magneto-resistive random access memory (MRAM), a phase change RAM (PRAM), etc., a volatile memory chip such as a DRAM, a mobile DRAM, a static RAM (SRAM), etc.

Alternatively, the first to eighth semiconductor chips 210, 220, 230, 240, 310, 320, 330 and 340 may include different types of semiconductor chips. For example, at least one of the first to eighth semiconductor chips 210, 220, 230, 240, 310, 320, 330 and 340 may include a memory chip, a logic chip, or a combination thereof.

The thicknesses T1a, T2a, T3a, T4a, T1b, T2b, T3b and T4b of the first to eighth semiconductor chips 210, 220, 230, 240, 310, 320, 330 and 340 may be substantially equal to or different from each other.

The stack chip package 10a may further include at least one passive element 400. The passive element 400 may be arranged outside the second sidewall portion of the first stack structure 200a and/or the fourth sidewall portion of the second stack structure 300a. The passive element 400 may include at least one of a capacitor, a register, and an inductor. The passive element may function as a decoupling, a noise filtering, resonance attenuation, a voltage control, etc. The passive element 400 may be arranged in the stack chip package 10a together with the semiconductor chips to improve the electrical characteristics and the signal characteristics of the stack chip package 10a.

The stack chip package 10a may further include a mold layer 500. The mold layer 500 may cover the first and second stack structures 200a and 300a to protect the first to eighth semiconductor chips 210, 220, 230, 240, 310, 320, 330 and 340 and seal the first surface 101 of the package substrate 100. The mold layer 500 may include various dielectric materials or insulation materials. For example, the mold layer 500 may include an epoxy molding compound (EMC).

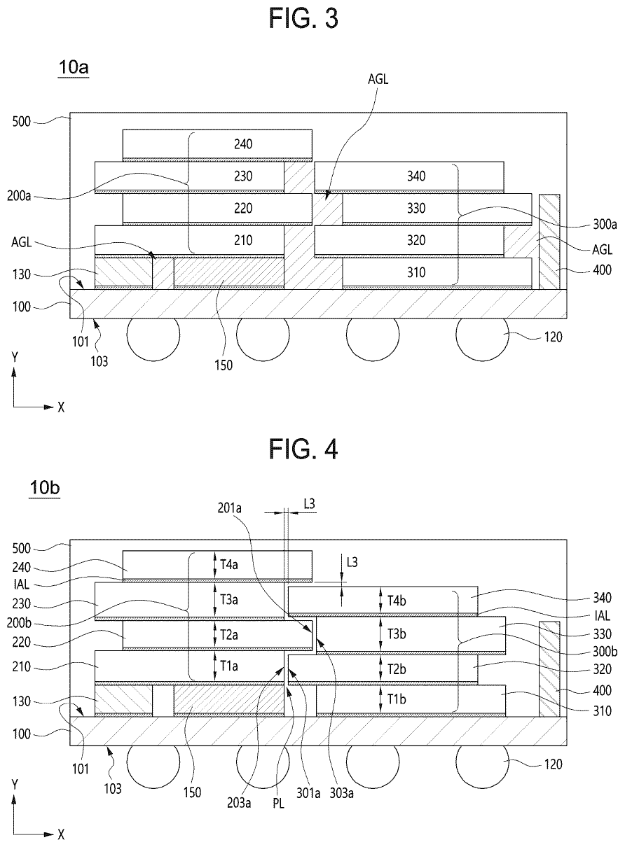

FIGS. 3 to 12 are cross-sectional views illustrating a stack chip package in accordance with embodiments of the present disclosure.

Referring to FIG. 3, a stack chip package 10a may further include an air gap layer AGL between the first sidewall portion of the first stack structure 200a and the third sidewall portion of the second stack structure 300a. In addition to be formed between the first stack structure 200a and the second stack structure 300a, the air gap layer AGL may also be formed between the support 130 and the control chip 150, and between the second stack structure 300a and the passive element 400. Thus, a relatively narrow space between the first and second stack structures 200a and 300a and between the second stack structure 300a and the passive element 400 may be electrically isolated from each other by the air gap layer AGL. Outer portions of the first stack structure 200a, the second stack structure 300a and the passive element 400 may be covered by the mold layer 500.

Referring to FIG. 4, a stack chip package 10b may include a package substrate 100, a first stack structure 200b and a second stack structure 300b.

The first stack structure 200b and the second stack structure 300b may be substantially the same as the first stack structure 200a and the second stack structure 300a in FIGS. 1 to 3, respectively.

In some embodiments, a whole surface of the first sidewall portion in the first stack structure 200b may be spaced apart from a whole surface of the third sidewall portion in the second stack structure 300b by a uniform gap L3.

That is, the first protrusion 201a of the first stack structure 200b may be inserted into the second concave portion 303a of the second stack structure 300b. The third protrusion 301a of the second stack structure 300b may be inserted into the first concave portion 203a of the first stack structure 200b. The thicknesses T1a, T2a, T3a, T4a, T1b, T2b, T3b and T4b of the first to eighth semiconductor chips 210, 220, 230, 240, 310, 320, 330 and 340 may be optimally selected to maintain the gap L1 between the first sidewall portion of the first stack structure 200b and the first sidewall portion of the second stack structure 300b. An insulating protection layer PL may be formed on the first and second protrusions 201a and 301a overlapped with each other at the first and third sidewall portions to maintain the electrical characteristics of the first to eighth semiconductor chips 210, 220, 230, 240, 310, 320, 330 and 340. For example, the insulating protection layer PL may be formed according to well-known methods. Alternately, the insulating protection layer PL may include an air.

According to some embodiments, because the uniform gap may be formed between the whole surface of the first sidewall in the first stack structure 200b and the whole surface of the third sidewall in the second stack structure 300b, a sufficient space for the passive element 400 may be secured.

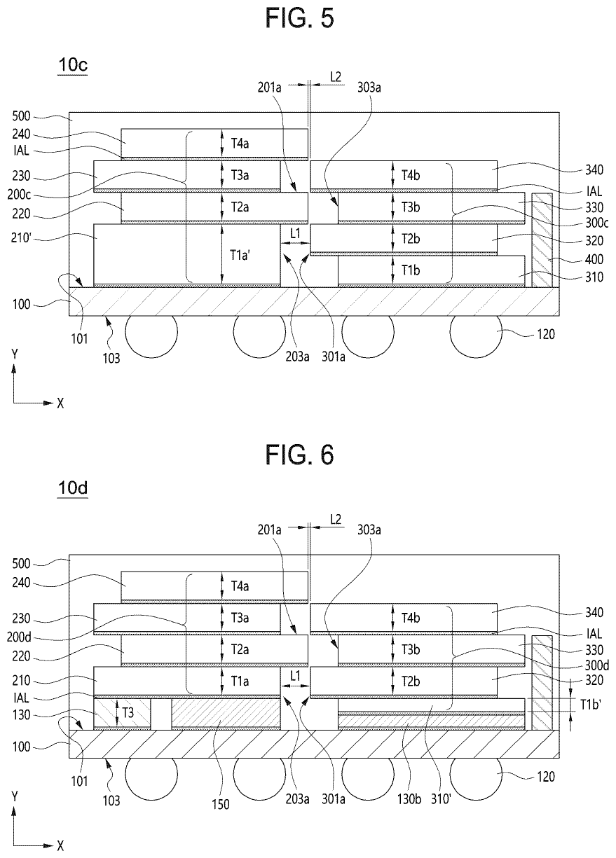

Referring to FIG. 5, a stack chip package 10c may include a semiconductor chip 210′ having a relatively thick thickness T1a′ without the support 130 and the control chip 150. For example, the thickness T1a′ of the first semiconductor chip 210′ may be a sum of the thicknesses T1b and T2b of the fifth and sixth semiconductor chips 310 and 320.

Referring to FIG. 6, when a fifth semiconductor chip 310′ of a stack chip package 10d has a thin thickness, to compensate the thickness of the fifth semiconductor chip 310′, a second support 130b may be arranged under the fifth semiconductor chip 310′.

In some embodiments, when the semiconductor chips have different thicknesses, a support may be applied. Alternatively, the thickness of the semiconductor chip and the height of the stack structure may be compensated without the support.

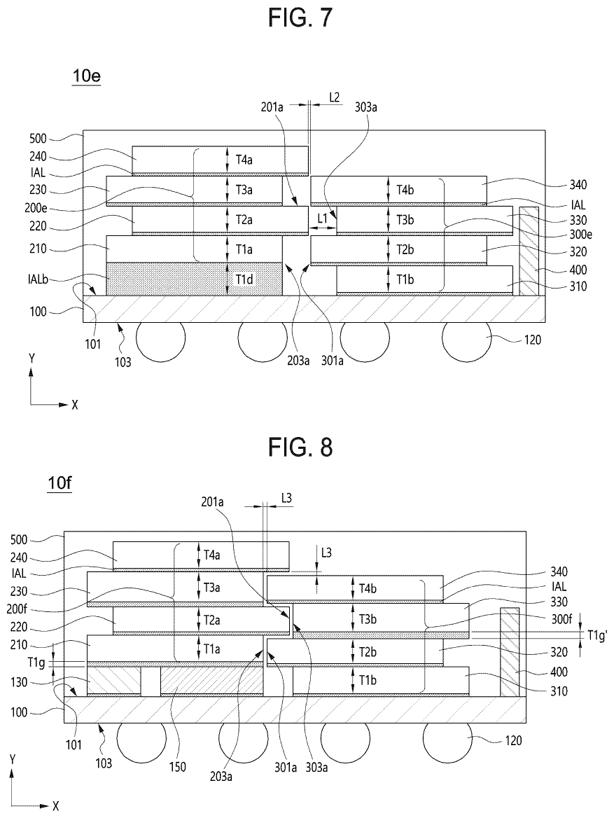

Referring to FIG. 7, a stack chip package 10e may include a lower insulating adhesive layer IALb having a relatively thick thickness T1d in place of the first support 130 and the control chip 150. The lower insulating adhesive layer IALb may be arranged under a first stack structure 200e to compensate a height of the first stack structure 200e.

Referring to FIG. 8, when the facing semiconductor chips 210, 220, 230, 240, 310, 320, 330 and 340 in a stack chip package 10f have different thicknesses, the thicknesses of the insulating adhesive layer IAL may be controlled to match the thicknesses of the semiconductor chips 210, 220, 230, 240, 310, 320, 330 and 340 with each other.

For example, when the thickness T2a of the second semiconductor chip 220 may be thicker than the thickness T3b of the seventh semiconductor chip 330, a thickness T1g of the insulating adhesive layer IAL under the second semiconductor chip 210 may be thinner than the thickness T1g′ of the insulating adhesive layer IAL under the seventh semiconductor chip 330.

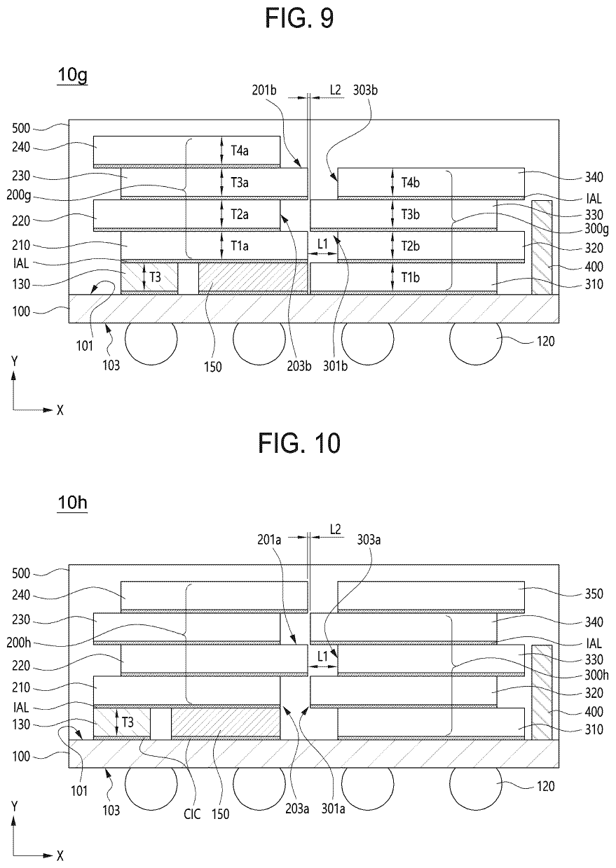

In some embodiments, the even numbered semiconductor chips 220 and 240 in the first stack structures 200a˜200f may be protruded toward the second stack structures 300a˜300f. The even numbered semiconductor chips 320 and 340 in the second stack structures 300a˜300f may be protruded toward the first stack structures 200a˜200f, but the embodiments are not limited thereto. For example, as shown in FIG. 9, the odd numbered semiconductor chips 210 and 230 in a first stack structure 200g may be protruded toward a second stack structure 300g. The odd numbered semiconductor chips 310 and 330 in the second stack structure 300g may be protruded toward the first stack structure 200g.

Referring to FIG. 10, in a stack chip package 10h, numbers of the semiconductor chips in a first stack structure 200h may be different from numbers of the semiconductor chips in a second stack structure 300h.

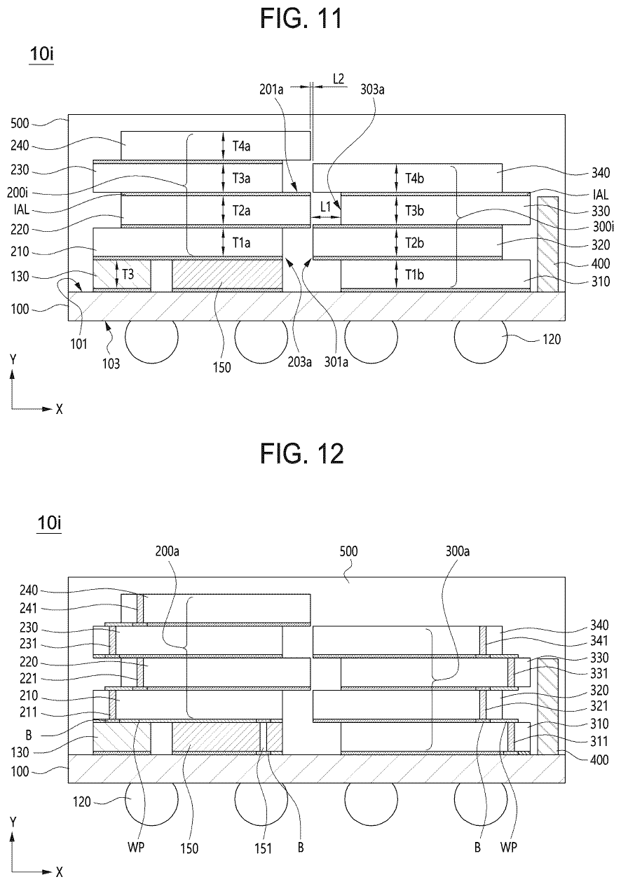

The insulating adhesive layer IAL may be positioned under the semiconductor chips 210, 220, 230, 240, 310, 320, 330 and 340, but the embodiments are not limited thereto. For example, as shown in FIG. 11, the insulating adhesive layer IAL may be positioned over and/or under the semiconductor chips 210, 220, 230, 240, 310, 320, 330 and 340.

In some embodiments, the semiconductor chips 210, 220, 230, 240, 310, 320, 330 and 340 in the stack structures of the stack chip packages 10a˜10i may be electrically connected with each other through bonding wires W, but the embodiments are—not limited thereto. For example, as shown in FIG. 12, the semiconductor chips 210, 220, 230, 240, 310, 320, 330 and 340 may be electrically connected with each other by through silicon vias (TSV) 211, 221, 231, 241, 311, 321, 331 and 341.

A reference numeral B may be a bump. A reference numeral WP may be a redistribution pattern configured to electrically connect upper and lower TSVs with each other.

Further, the package substrate 100 may include an inner wiring configured to electrically connect the first stack structure 200a with the second stack structure 300a. The package substrate 100 may include an external terminal 120 on the second surface 103 such as a solder ball or a solder bump configured to couple the package substrate 100 with an external device.

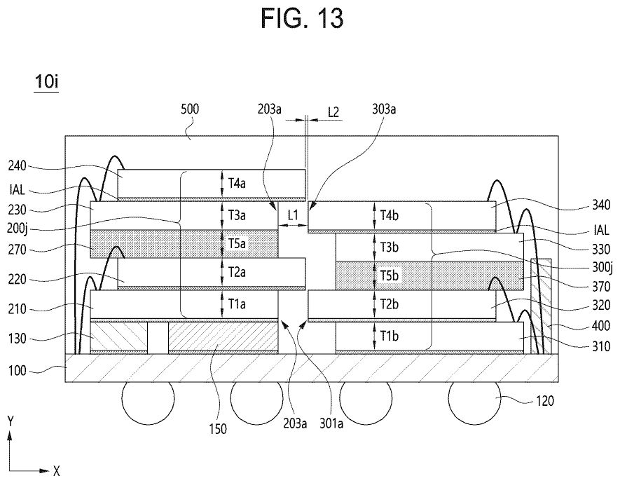

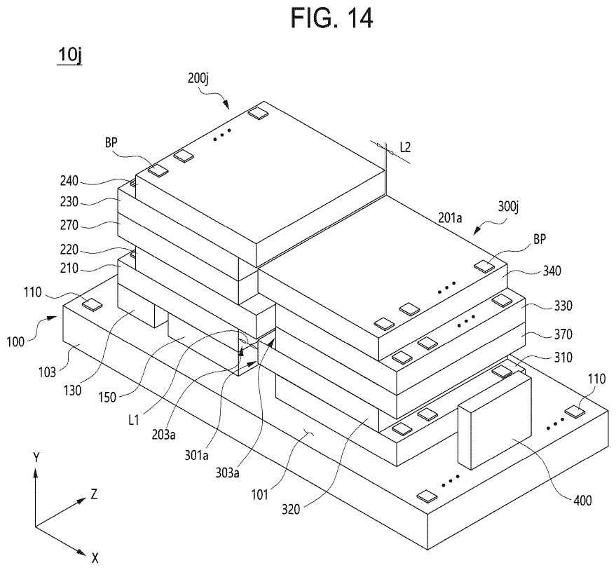

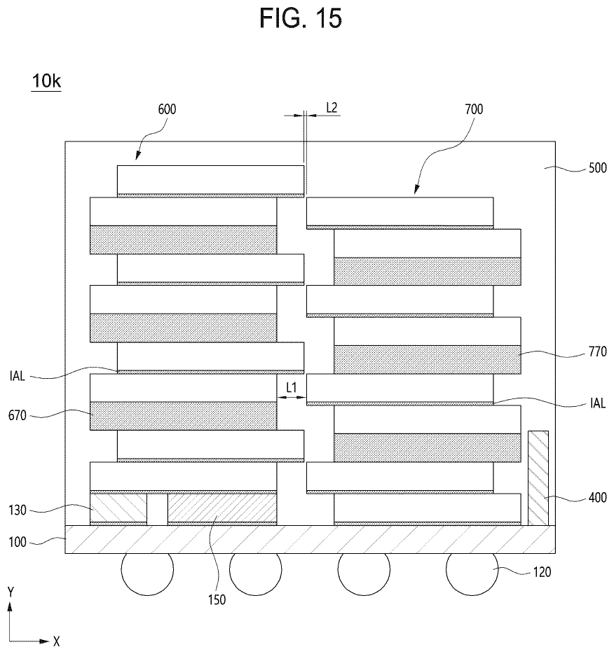

FIG. 13 is a cross-sectional view illustrating a stack chip package with a gap-forming layer in accordance with an embodiment of the present disclosure, FIG. 14 is a perspective view illustrating a stack chip package with a gap-forming layer and FIG. 15 is a cross-sectional view illustrating a stack chip package in accordance with embodiments of the present disclosure.

Referring to FIGS. 13 and 14, at least one of first and second stack structures 200j and 300j in a stack chip package 10j may further include gap-forming layers 270 and 370.

For example, the first stack structure 200j may include the at least one first gap-forming layer 270. The second stack structure 300j may include the at least one second gap-forming layer 370.

In some embodiments, the gap-forming layer 270 may increase a thickness (T3a+T5a) of the concave portion 203a of the semiconductor chip 230, thereby widening a gap between the first and second stack structures 200j and 300j from L2 to L1. The gap-forming layer 370 may increase a thickness (T3b+T5b) of the concave portion 303a of the semiconductor chip 330, thereby widening a gap between the first and second stack structures 200j and 300j from L2 to L1. Thus, a loop height of the bonding wire BL between the semiconductor chips stacked in the vertical direction Y may be secured.

A reference numeral BP refers to bonding pads of the semiconductor chips. The bonding pads BP may be electrically connected with the pads 110 of the package substrate 100 through the bonding wires BW.

In FIG. 15, an X-direction is the direction on which the first and second stack structures 200j and 300j may be arranged side by side. A Y-direction is the stack direction of the first to eighth semiconductor chips 210, 220, 230, 240, 310, 320, 330 and 340. Also a Z-direction is a direction on which a plurality of chip connection patterns on the substrate may be arranged side by side.

In some embodiments, one stack structure may include one gap-forming layer, but the embodiments are not limited thereto. For example, as shown in FIG. 15, the gap-forming layer may be formed between the semiconductor chips in the stack structure.

According to various embodiments, the stack chip package with the stack structures may include the semiconductor chips arranged in a zigzag pattern to secure the integration area of the passive element.

Therefore, by integrating the passive element in the stack chip package, integrity of the signal and the power may be secured. That is, an overall footprint area of the stack chip package may be reduced.

The above described embodiments of the present disclosure are intended to illustrate and not to limit the present invention. Various alternatives and equivalents are possible. The invention is not limited by the embodiments described herein. Nor is the invention limited to any specific type of semiconductor device. Other additions, subtractions, or modifications which are obvious in view of the present disclosure are intended to fall within the scope of the appended claims. Furthermore, the embodiments may be combined to form additional embodiments.

What is claimed is:

1. A stack chip package comprising:
a first stack structure including a plurality of semiconductor chips stacked on a package substrate, the first stack structure including a first sidewall portion and a second sidewall portion, wherein the plurality of the semiconductor chips in the first stack structure are stacked to alternately form a first concave portion and a first protrusion at the first sidewall portion;
a second stack structure including a plurality of semiconductor chips stacked on the package substrate, the second stack structure including a third sidewall portion facing the first sidewall portion and a fourth sidewall portion, wherein the plurality of the semiconductor chips in the second stack structure are stacked to alternately form a second concave portion and a second protrusion at the third sidewall portion; and
a passive element integrated on the package substrate outside the second sidewall portion of the first stack structure and/or the fourth sidewall portion of the second stack structure,
wherein the first concave portion of the first stack structure faces the second protrusion of the second stack structure and the first protrusion of the first stack structure faces the second concave portion of the second stack structure.

2. The stack chip package of claim 1, wherein a thickness of the first concave portion corresponds to a thickness of the second protrusion and a thickness of the first protrusion corresponds to a thickness of the second concave portion.

3. The stack chip package of claim 1, further comprising an insulating adhesive layer configured to attach the plurality of the semiconductor chips of the first stack structure to each other and the plurality of the semiconductor chips of the second stack structure to each other.

4. The stack chip package of claim 3,
wherein a thickness of the first concave portion and the first protrusion is a sum of a thickness of each of the semiconductor chips in the first stack structure and a thickness of the insulating adhesive layer attached to the semiconductor chips of the first stack structure, and
wherein a thickness of the second concave portion and the second protrusion is a sum of a thickness of each of the semiconductor chips in the second stack structure and a thickness of the insulating adhesive layer attached to the semiconductor chips of the second stack structure.

5. The stack chip package of claim 3, wherein at least one of the first stack structure and the second stack structure comprises a semiconductor chip having a relatively thin thickness, and wherein the insulating adhesive layer attached to the semiconductor chip having the relatively thin thickness has a thickness thicker than a thickness of the insulating adhesive layer attached to other semiconductor chips.

6. The stack chip package of claim 1, further comprising a control chip arranged between the first stack structure and the package substrate.

7. The stack chip package of claim 6, wherein the control chip has a size smaller than a size of the semiconductor chips in the first stack structure, the control chip is positioned adjacent to the first sidewall portion of the first stack structure to form a space between the first stack structure and the package substrate, and a support is arranged in the space between the first stack structure and the package substrate.

8. The stack chip package of claim 6, wherein a height from the package substrate to an uppermost portion of the first stack structure is higher than a height from the package substrate to an uppermost portion of the second stack structure.

9. The stack chip package of claim 6, wherein a height from the package substrate to an uppermost portion of the first stack structure is substantially the same as a height from the package substrate to an uppermost portion of the second stack structure.

10. The stack chip package of claim 1, wherein the adjacent first and second protrusions are spaced apart from each other by a first gap, and wherein the first concave portion and the second protrusion facing each other and first protrusion and the second concave portion facing each other are spaced apart from each other by a second gap wider than the first gap.

11. The stack chip package of claim 1, wherein the adjacent first and second protrusion are spaced apart from each other by a gap, the first concave portion and the second protrusion facing each other are spaced apart from each other by the gap, and the first protrusion and the second concave portion facing each other are spaced apart from each other by the gap.

12. The stack chip package of claim 1, further comprising an air gap layer positioned between the first sidewall portion of the first stack structure and the third sidewall portion of the second stack structure.

13. The stack chip package of claim 1, further comprising a connection member configured to connect the semiconductor chips of the first stack structure with each other, the semiconductor chips of the second stack structure with each other, the semiconductor chips of the first stack structure with the package substrate, and the semiconductor chips of the second stack structure with the package substrate.

14. The stack chip package of claim 13, wherein the connection member comprises at least one of a bonding wire and a through silicon via (TSV).

15. The stack chip package of claim 1, further comprising a gap-forming layer interposed between the semiconductor chips of the first stack structure and/or between the semiconductor chips of the second stack structure to secure thicknesses of the first and second concave portions and thicknesses of the first and second protrusions.

16. The stack chip package of claim 1, wherein numbers of the semiconductor chips in the first stack structure are substantially equal to or different from numbers of the semiconductor chips in the second stack structure.

17. A stack chip package comprising:
a package substrate;
a first stack structure including a plurality of semiconductor chips stacked on the package substrate in a zigzag pattern to expose edge pads of each of the semiconductor chip, the first stack structure including a first sidewall portion and a second sidewall portion, and the first sidewall portion including a first concave portion and a first protrusion alternately stacked;
a second stack structure arranged at one side of the first sidewall portion of the first stack structure, the second stack structure including a plurality of semiconductor chips stacked on the package substrate in a zigzag pattern to expose edge pads of the semiconductor chips, the second stack structure including a third sidewall portion facing the first sidewall portion and a fourth sidewall portion, and the third sidewall portion including a second concave portion and a second protrusion alternately stacked; and
a passive element integrated on the package substrate outside the second sidewall portion of the first stack structure and/or the fourth sidewall portion of the second stack structure,
wherein the first concave portion of the first stack structure faces the second protrusion of the second stack structure and the first protrusion of the first stack structure faces the second concave portion of the second stack structure.

18. The stack chip package of claim 17,
wherein the first sidewall portion of even numbered semiconductor chips among the plurality of the semiconductor chips in the first stack structure is protruded from the first sidewall portion of odd numbered semiconductor chips among the plurality of the semiconductor chips in the first stack structure toward the second stack structure to form the first concave portions at the first sidewall portions of the odd numbered semiconductor chips and the first protrusions at the first sidewall portions of the even numbered semiconductor chips,
wherein the third sidewall portion of even numbered semiconductor chips among the plurality of the semiconductor chips in the second stack structure is protruded from the third sidewall portion of odd numbered semiconductor chips among the plurality of the semiconductor chips in the second stack structure toward the first stack structure to form the second concave portions at the third sidewall portions of the odd numbered semiconductor chips and the second protrusions at the third sidewall portions of the even numbered semiconductor chips, and
wherein a support is inserted into at least one of the first stack structure and the second stack structure to face the first concave portion and the second protrusion to each other and the first protrusion and the second concave portion to each other.

19. The stack chip package of claim 17, wherein a distance between the first concave portion and the second protrusion facing each other is substantially the same as a distance between the first protrusion and the second concave portion facing each other.

20. The stack chip package of claim 17, wherein a distance between the first concave portion and the second protrusion facing each other, a distance between the first protrusion and the second concave portion facing each other, and a distance between the adjacent first and second protrusions are substantially equal to each other.

21. A stack chip package comprising:
first and second stack structures positioned adjacent to each other, wherein each of the first and second stack structures has uneven sidewalls including alternating protruding and concave portions, and
wherein a concave portion of one of the first stack structures is positioned adjacent to a concave portion of the second stack structure and vice versa thus reducing the overall footprint area of the stack chip package.
